(19) United States
(12) Patent Application Publication
(10) Pub. No.: US 2020/0031199 A1
(43) Pub. Date: Jan. 30, 2020

(54) PTC HEATER

(71) Applicants: HYUNDAI MOTOR COMPANY, Seoul (KR); KIA MOTORS CORPORATION, Seoul (KR); Hanon Systems, Daejeon (KR)

(72) Inventors: Sang Yeop Lee, Suwon-si (KR); Jae Sik Choi, Suwon-si (KR); Su Yeon Kang, Seoul (KR); Chae Geun Lim, Daejeon (KR); Sang Ho Oh, Daejeon (KR); Joong Heum Jung, Daejeon (KR); Jun Ho Choi, Daejeon (KR)

(73) Assignees: HYUNDAI MOTOR COMPANY, Seoul (KR); KIA MOTORS CORPORATION, Seoul (KR); Hanon Systems, Daejeon (KR)

(21) Appl. No.: 16/196,869

(22) Filed: Nov. 20, 2018

(30) Foreign Application Priority Data
Jul. 25, 2018 (KR) 10-2018-0086307

(51) Int. Cl. B60H 1/22; B60H 1/00; B60N 2/56

(52) U.S. Cl. CPC B60H 1/2225; B60H 1/00285; H01L 29/7393; B60H 1/2218; B60N 2/5685; B60H 1/00385

(57) ABSTRACT

A PTC heater includes PTC heater parts in which heater rods and radiation fins are alternately arranged. A frame is formed along a circumference to support the PTC heater parts. IGBT elements are installed on the frame and selectively apply a battery current to each of the heater rods to adjust the heat generation amount of the heater rods. A control module is installed on the frame and controls the IGBT elements to adjust the heat generation amount of the heater rods according to a target temperature value. A heat sink is installed on the frame, is connected with the IGBT elements for heat-exchange, is formed to pass the PTC heater parts in the horizontal direction and radiate heat of the IGBT elements through the flowing air inside the air conditioning case.

### CROSS REFERENCE TO RELATED APPLICATION

The present application claims priority to and the benefit of Korean Patent Application No. 10-2018-0086307 filed on Jul. 25, 2018, the entire contents of which are incorporated herein for all purposes by this reference.

### BACKGROUND OF THE DISCLOSURE

### Field of the Disclosure

The present disclosure relates to a PTC heater that maximizes the efficiency of the dual air conditioning system in which the air conditioning systems of the driver's and passenger's seats are set to be different from each other.

### Description of the Related Art

Generally, a vehicle is equipped with an air conditioner system to control the interior temperature of the vehicle.

In the case of an internal combustion engine vehicle, the air conditioner system is provided with a heat exchanger installed at the circulation pipe of the coolant. The temperature inside the vehicle is controlled by moving the air to the heat exchanger.

In typical vehicles, heating systems are mainly designed to use the waste heat of the engine. A hybrid vehicle and an electric vehicle cannot obtain the waste heat or engine coolant required for heating because of limited use of the engine or no use of the engine.

Therefore, a Positive Temperature Coefficient (PTC) heater, which is an electric heater capable of heating the interior of the vehicle without engine coolant, has been used in an air conditioning system of a hybrid vehicle and an electric vehicle.

The above-mentioned PTC heater uses a small low voltage PTC heater for a general air conditioning system and a large high voltage PTC heater for an electric vehicle and a hybrid vehicle.

Specifically, the PTC heater includes a plurality of heat generating rods and heat radiating fins installed between the plurality of heat generating rods. Particularly, the heat generating rods are equipped with a PTC device and the amount of heat generated by the PTC device is controlled by the electric signal control applied thereto.

In addition, a control module composed of a microcomputer and a plurality of insulated gate bipolar transistor (IGBT) elements are installed on a side surface of a case of the PTC elements. The microcomputer outputs a “duty ratio” for controlling the heat generation amount of the PTC heater. The insulated gate bipolar transistor (IGBT) elements correspond to the heat generating rods to control the current of the battery applied to each heat generating rods according to the “duty ratio” of the microcomputer.

Particularly, the IGBT elements perform pulse width modulation (PWM) switching control while periodically turning on/off the applied current of the heat generating rods based on the “duty ratio” of the microcomputer, which generates heat in the elements.

In order to radiate this heat, conventionally, a heat sink structure has been provided which contacts with the IGBT elements for heat exchange and extends to the inside of the air conditioning case in order to radiate the heat of the IGBT elements through the discharge air flowing through the air conditioning case. This reduces the temperature of the IGBT elements to prevent failure of the elements from being occurred.

In general, the PTC heater is divided into one side area for heating the driver's seat the other side area for heating the passenger's seat. A duct door provided on the upstream side of the PTC heater selectively blocks the air flow to one area region or the other side area of the PTC heater so that the air conditioning system of the driver's and the passenger's seats can be controlled differently.

For example, when the driver's seat is cooling-conditioned and the passenger's seat is heating-controlled, the duct door operates to block the upstream portion of one side area of the PTC heater so that air heats only the passenger's seat through the other side area of the PTC heater.

At this time, since the air flow of the heat sink is blocked by the duct door so as not to radiate heat, the IGBT elements are overheated. In order to cool the IGBT elements, the duct door is restored to its original state again and the cooling control of the driver's seat is stopped. As a result, there was a problem that proper air conditioning control of the driver's and passenger's seats cannot be performed.

The foregoing is intended merely to aid in understanding the background of the present disclosure. The foregoing is not intended to be understood that the present disclosure falls within the purview of the related art that is already known to those skilled in the art.

### SUMMARY OF THE DISCLOSURE

Accordingly, the present disclosure is provided, keeping in mind the above problems occurring in the related art. The present disclosure is intended to propose to a PTC heater, which can smoothly perform dual air conditioning by preventing overheating of the PTC whereby the heat of the IGBT elements are smoothly radiated even if different air conditioning systems are required for the driver's and passenger's seats.

A PTC heater according to the present disclosure, in order to achieve the above objective, may include PTC heater parts formed so that heater rods and radiation fins arranged in the horizontal direction within an air conditioning case are alternately disposed to each other. The PTC heater may also include a frame formed along the circumference to support the PTC heater parts and a plurality of IGBT elements installed on the frame and selectively applying a battery current to each heater rods of the PTC heater parts in order to adjust the heat generation amount of the heater rods. The PTC heater may also include a control module installed on the frame and controlling the IGBT elements in order to adjust the heat generation amount of the heater rods of the PTC heater parts according to a target temperature value. The PTC heater may also include a heat sink installed on the frame, connected with the plurality of IGBT elements to heat-exchange, formed to pass the PTC heater parts in the horizontal direction, and radiating the heat of the plurality of IGBT elements through the flowing air within the air conditioning case.

The plurality of IGBT elements may be installed on an upper portion or a lower portion of the frame together with the heat sink, and the control module may be installed at one side portion of the frame.

The control module may be configured to include a receiving part installed at the one side portion of the frame and provided with an internal space. The control module may also be configured to include a microcomputer stored in the internal space of the receiving part to output the signal for adjusting the heat generation amount of the heater rods to the plurality of IGBT elements.

The PTC heater parts may be composed of a first PTC heater part and a second PTC heater part arranged in parallel at a position spaced apart from each other in the horizontal direction within the air conditioning case.

One side portion of the heat sink may be installed at the upper portion or the lower portion of the frame to couple with the plurality of IGBT elements to exchange heat. The other side portion of the heat sink may be installed at the one side portion of the frame to couple with the control module to exchange heat.

The one side portion of the heat sink may be formed such that an area of a region facing the first PTC heater part is equal to an area of a region facing the second PTC heater part.

The control module may adjust the heat generation amount of the heater rods of the first PTC heater part according to a driver's seat target temperature value and the heat generation amount of the heater rods of the second PTC heater part according to a passenger's seat target temperature value.

A horizontal direction cross-sectional area of the first PTC heater part may be equal to a horizontal direction cross-sectional area of the second PTC heater part.

A separation wall of insulation material may be included that fills the space between the first and second PTC heater parts to define the first and second PTC heater parts.

The separation wall may be integrally formed with the frame.

In accordance with the PTC heater having the above-described structure, even if the dual air conditioning, which is the driver's seat cooling and the passenger's seat heating, is carried out, the heat of the plurality of IGBT elements can be smoothly radiated through the heat sink so that the air conditioning corresponding to the occupant's demand is provided. This ultimately improves the merchantability of the vehicle.

In addition, by arranging the heater rods to extend in the vertical direction with respect to the air conditioning case, it is possible to distinguish the heating zone for the driver's seat and the passenger's seat control.

As a result, it is possible to individually control the PTC operation and temperature of the driver's seat and the passenger's seat, and whether or not the PTC heater is operating, thereby reducing power consumption through reducing unnecessary power consumption and increasing the travel distance in case of an electric vehicle.

In addition, the heat sink is provided so that the areas facing the first and the second PTC heater parts are equal to each other. Thus, it is possible to prevent the heating unbalance of the driver's seat and the passenger's seat due to the difference in the heat radiation area being prevented.

### BRIEF DESCRIPTION OF THE DRAWINGS

The above and other objects, features, and other advantages of the present disclosure will be more clearly understood from the following detailed description when taken in conjunction with the accompanying drawings, in which:

FIG. 1 is an assembly drawing showing a PTC heater according to an embodiment of the present disclosure;

FIG. 2 is a cross-sectional view of the PTC heater of FIG. 1 according to an embodiment of the present disclosure;

FIG. 3 is a drawing showing the air flow in the air conditioning system including the PTC heater of FIGS. 1 and 2; and

FIG. 4 is a perspective view showing a heat sink mounted on the PTC heater of FIGS. 1 and 2.

### DETAILED DESCRIPTION OF THE DISCLOSURE

Hereinafter, a PTC heater according to an embodiment of the present disclosure is described with reference to the attached drawing.

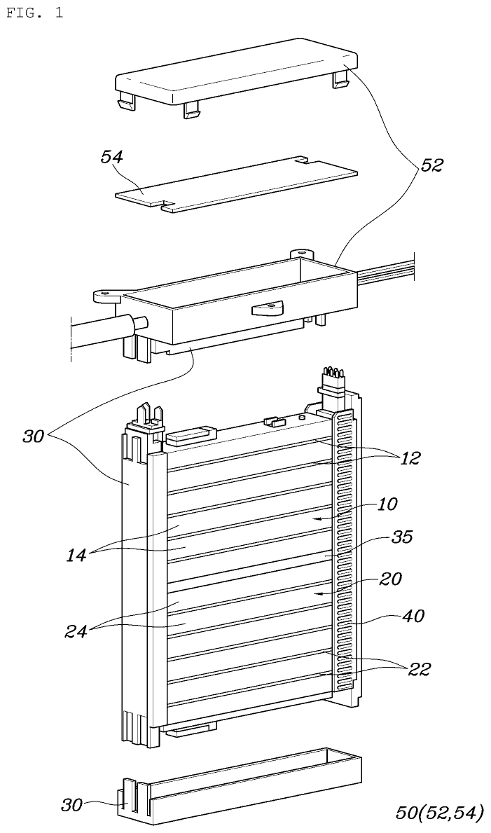

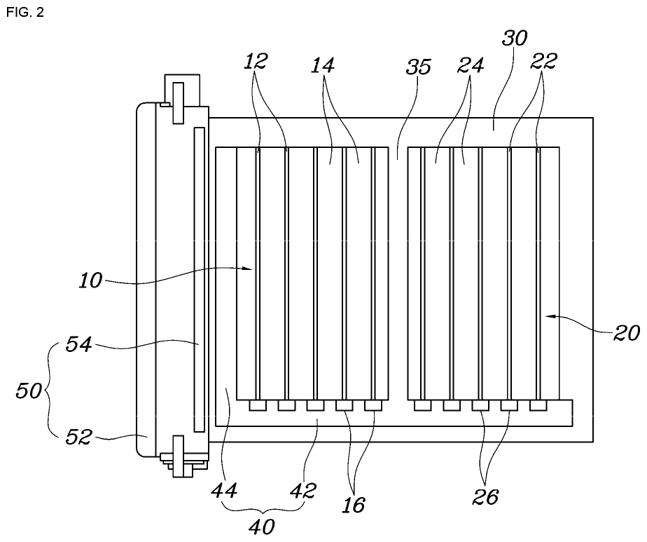

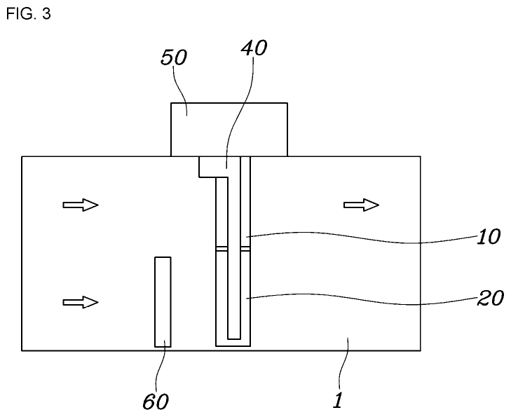

FIG. 1 is an assemble drawing showing a PTC heater according to an embodiment of the present disclosure. FIG. 2 is a cross-sectional view of a PTC heater according to an embodiment of the present disclosure. FIG. 3 is a drawing showing the air flow in the air conditioning system including the PTC heater.

Referring to FIG. 1 to FIG. 3, a PTC heater of the present disclosure may include PTC heater parts 10 and 20 in which heater rods 12 and 22 and radiation fins 14 and 24 extend in the vertical direction. The heater rods 12 and 22 and radiation fins 14 and 24 are alternately arranged in the horizontal direction within an air conditioning case 1. The PTC heater may include a frame 30 formed along the circumference to support the PTC heater parts 10 and 20. The PTC heater may include a plurality of IGBT elements 16 and 26 installed on the frame 30 and selectively applying a battery current to each heater rods 12 and 22 of the PTC heater parts 10 and 20 in order to adjust the heat generation amount of the heater rods 12 and 22. The PTC heater may include a control module 50 installed on the frame 30 and controlling the plurality of IGBT elements 16 and 26 in order to adjust the heat generation amount of the heater rods of the PTC heater parts 10 and 20 according to a target temperature value. The PTC heater may include a heat sink 40 installed on an upper portion or a lower portion of the frame 30. The heat sink 40 may be connected with the plurality of IGBT elements 16 and 26 to heat-exchange, i.e., for heat transfer or to exchange heat, and be formed to pass the PTC heater parts 10 and 20 in a horizontal direction and radiating the heat of the plurality of IGBT elements 16 and 26 through the flowing air within the air conditioning case 1.

The air conditioning case 1 has an inlet side provided with an air inlet and an exit side provided with a plurality of vents. The case 1 has an evaporator and a PTC heater installed and arranged to carry out cooling and heating of a vehicle.

The inside and outside air that flows into the air conditioning case 1 may become cold air while passing through the evaporator and may be heated while selectively passing through the PTC heater. The heat-exchanged inside and outside air may be discharged to the inside of the vehicle through the vents to cool and heat the interior of the vehicle.

In the present disclosure, the heater rods 12 and 22 and the radiation fins 14 and 24 form the PTC heater and may be arranged so as to extend in the vertical direction with respect to the air conditioning case 1.

Conventionally, the heater rods 12 and 22 are formed to extend in the horizontal direction with respect to the air conditioning case 1 and to be controlled at the same temperature in the left and right regions. However, in the present disclosure, the heat rods are formed to extend in the vertical direction so that the heat generation amount of the heater rods 12 and 22 can be easily controlled individually in the left and right regions. This serves to reduce power consumption in performing individual air conditioning of the driver's and the passenger's seats.

The PTC heater parts 10 and 20 may be surrounded and supported by a frame 30. The plurality of IGBT elements 16 and 26 may be installed on the frame 30 and apply a battery current to the heater rods 12 and 22. The control module 50 may be installed on the frame 30 and transmit control signals to the IGBT elements 16 and 26 according to the target temperature value.

The control module 50 may output a duty ratio in order to adjust the heat generation amount of the PTC heater. The plurality of IGBT elements 16 and 26 corresponded to each of the heater rods 12 and 22, respectively, and may serve to control a battery current applied to each of the heater rods 12 and 22 according to the duty ratio received by the control module 50.

In the present disclosure, the heat sink 40 is provided to radiate the heat generated while the plurality of IGBT elements 16 and 26 perform PWM switching control. The heat sink 40 is installed along the upper or lower portion of the frame 30, is connected with the plurality of IGBT elements 16 and 26 for exchanging heat, i.e. heat-exchange or heat transfer, and is formed to pass the PTC heater parts 10 and 20 in the horizontal direction.

That is, conventionally, the heat sink 40 is formed at one side portion of the frame 30 so that the plurality IGBT elements 16 and 26 is overheated. At the same time, heat radiation is not achieved when air flow toward the one side portion of the frame 30 is blocked by a duct door 60, which causes the phenomenon where individual air conditioning is stopped.

However, in the present disclosure, the heat sink 40 is formed along the upper portion or lower portion of the frame 30 to extend in the horizontal direction. Thus, even if the air flow in some areas is blocked by the duct door 60 at the upstream side of the PTC heater, the heat sink 40 is exposed in the remaining area. As a result, the heat radiation of the plurality of IGBT elements 16 and 26 through the heat sink 40 is continuously achieved, thereby preventing the individual air conditioning from being stopped due to the overheating phenomenon.

Therefore, it is possible to stably maintain individual air conditioning even when dual conditioning or individual air conditioning is required in which the driver's seat and the passenger's seat perform different cooling and heating air conditioning to each other This improves the stability and the commerciality of the vehicle.

In the present disclosure, the plurality of IGBT elements 16 and 26 may be provided at the upper or lower portion of the frame 30 together with the heat sink 40. The control module 50 may be arranged at the one side portion of the frame 30.

The heater rods 12 and 22 in the PTC heater parts 10 and 20 of the present disclosure are extended in the vertical direction of the air conditioning case 1. Thus, it may be desirable in terms of the volume of the package that the plurality of IGBT elements 16 and 26 are connected with the upper end portion or lower end portion of the heater rods 12 and 22 in order to apply the battery current to each of the heater rods 12 and 22.

Therefore, the plurality of IGBT elements 16 and 26 are provided at the upper or lower portion of the frame 30, so that the IGBT elements 16 and 26 are arranged close to the heater rods 12 and 22, thereby minimizing the overall package volume of the PTC heater.

In addition, the plurality of IGBT elements 16 and 26 may be positioned at a portion where the heat sink 40 is provided among the upper or lower portion of the frame 30, so that the IGBT elements 16 and 26 and the heat sink 40 are connected with each other to easily heat-exchange, thereby minimizing the package volume.

On the other hand, the control module 50 can be installed at the one side portion of the frame 30, which does not largely change the shape of the conventional PTC heater shape, thereby facilitating the design. The plurality of IGBT elements 16 and 26 may be electrically connected with the control module 50 to receive the control signals of the control module 50.

The control module 50 may include a receiving part 52 installed at the one side portion of the frame 30 and may be provided with an internal space. The control module 50 may include a microcomputer 54 stored in the internal space of the receiving part 52 to output the signal for adjusting the heat generation amount of the heater rods 12 and 22 to the plurality of IGBT elements 16 and 26.

Therefore, a microcomputer unit for transmitting the control signal to the IGBT elements 16 and 26 may be installed at the one side portion of the frame 30.

On the other hand, the PTC heater in the present disclosure may be composed of a first PTC heater part 10 and a second PTC heater part 20 provided in parallel to each other in the horizontal direction in the air conditioning case 1.

The control module 50 may adjust the heat generation amount of the heater rods 12 of the first PTC heater part 10 according to a driver's seat target temperature value. The control module 50 may also adjust the heat generation amount of the heater rods 22 of the second PTC heater part 20 according to a passenger's seat target temperature value.

In the present disclosure, the PTC heater may be arranged to divide the heated area into two sections of the first PTC heater part 10 and the second PTC heater part 20, thereby controlling each PTC temperature of the driver's seat and the passenger's seat.

Therefore, it is able to turn off the PTC function of the driver's seat or passenger's seat in the individual air conditioning, thereby reducing power consumption. In an electric vehicle, this can have the effect of increasing travel distance of the vehicle.

In addition, independent PTC temperature control on the left and right is possible, so that customer satisfaction can be improved by clearly ensuring the difference in discharge temperature according to the driver's seat and the passenger's seat temperature setting.

On the other hand, one side portion 42 of the heat sink 40 may be installed at the upper or lower portion of the frame 30 to couple with the plurality of IGBT elements 16 and 26 to heat-exchange or transfer heat. The other side portion 44 of the heat sink 40 may be installed at the one side portion of the frame 30 to couple with the control module 50 to heat-exchange or transfer heat.

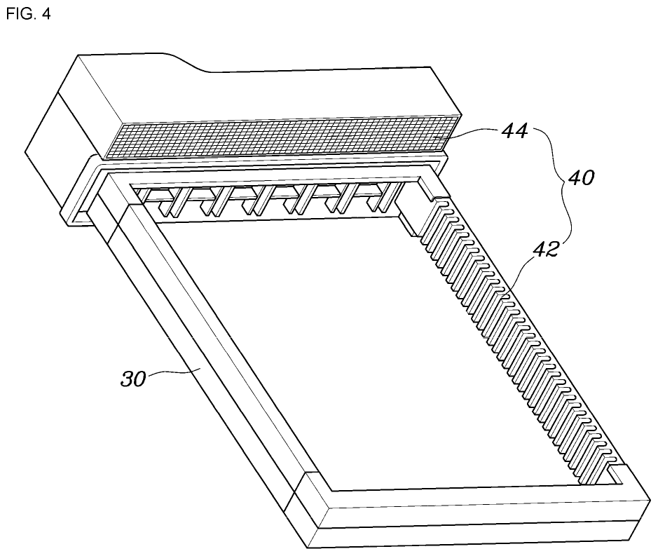

FIG. 4 is a perspective view showing the heat sink 40 mounted on the PTC heater. As shown in FIG. 4, the plurality of IGBT elements 16 and 26 may be provided at the upper or lower portion of the frame 30. The microcomputer 54 of the control module 50 may be provided at the one side portion of the frame 30. It is desirable to form the heat sink 40 to be extended along the upper or lower portion and one side portion of the frame 30 in order to properly radiate the heat of the IGBT elements 16 and 26 and the microcomputer 54 generated by the PWM switching control.

The plurality of IGBT elements 16 and 26, as shown in FIG. 1, may be provided in the heat sink 40 so as to heat-exchange or transfer heat.

Referring to FIG. 1 to FIG. 3 again, the one side portion 42 of the heat sink 40 may be formed to have the same area of the region facing the first PTC heater part 10 as the area of the region facing the second PTC heater part 20.

That is, the heat sink 40 is formed so that the radiation areas facing the first PTC heater part 10 and the second PTC heater part 20 are equal to each other, so that the same heat radiation performance in the first and second PTC heater parts 10 and 20 can be achieved. This can thereby prevent the heating of the driver's seat and the passenger's seat from being unbalanced. This improves the air conditioning control performance of the vehicle.

Furthermore, the horizontal direction cross-sectional area of the first PTC heater part 10 and the horizontal direction cross-sectional area of the second PTC heater part 20 may be equal to each other.

Therefore, it is possible to improve the air conditioning control performance of the vehicle by allowing the heating of the driver's seat and the passenger's seat to be performed in a balanced manner.

On the other hand, the PTC heater of the present disclosure may further include a separation wall 35 of insulation material that fills the space between the first and second PTC heater parts 10 and 20 to define the first and second PTC heater parts 10 and 20.

Therefore, the first PTC heater part 10 and the second PTC heater part 20 are each provided to control the heating temperature. The insulation wall 35 may be integrally formed with the frame 30.

In accordance with the PTC heater having the above-described structure, even if the dual air conditioning, which is the driver's seat cooling and the passenger's seat heating, is carried out, the heat of the IGBT elements can be smoothly radiated through the heat sink. This thereby provides the air conditioning corresponding to the occupant's demand to ultimately improve the merchantability of the vehicle.

Furthermore, the heater rods are provided to extend in the vertical direction with respect to the air conditioning case. Thus, it is possible to distinguish heating zones for the driver's seat and the passenger's seat control.

Since the PTC heater can be controlled to operate or not operate and temperatures of the driver's seat and the passenger's seat can be individually controlled, unnecessary consumption of energy is reduced. Thus, power consumption can be reduced and the travel distance of the electric vehicle can be increased.

In addition, since the heat sink is arranged so that the areas facing each of the first and the second PTC heater parts are equal to each other, it is possible to prevent the heating unbalance of the driver's seat and the passenger's seat due to the difference in the heat radiation area.

Although specific embodiments of the present disclosure has been described and illustrated herein, those having ordinary skill in the art will appreciate that various alterations and modifications are possible without departing from the technical spirit of the present disclosure as disclosed in the appended claims.

What is claimed is:

1. A PTC heater comprising:
PTC heater parts formed so that heater rods and radiation fins arranged within an air conditioning case are alternately disposed to each other;
a frame formed along a circumference of the PTC heater to support the PTC heater parts;
a plurality of IGBT elements being installed on the frame and selectively applying a battery current to each of the heater rods of the PTC heater parts in order to adjust the heat generation amount of the heater rods;
a control module being installed on the frame and controlling the plurality of IGBT elements in order to adjust the heat generation amount of the heater rods of the PTC heater parts according to a target temperature value; and
a heat sink being installed on the frame, connected with the plurality of IGBT elements to heat-exchange, formed to pass the PTC heater parts in the horizontal direction, and radiating the heat of the plurality of IGBT elements through the flowing air within the air conditioning case.

2. The PTC heater of claim 1, wherein:
the plurality of IGBT elements are installed on an upper portion or a lower portion of the frame together with the heat sink; and
the control module is installed at one side portion of the frame.

3. The PTC heater of claim 2, wherein the control module is configured to include:
a receiving part installed at the one side portion of the frame and being provided with an internal space; and
a microcomputer stored in the internal space of the receiving part to output a signal for adjusting the heat generation amount of the heater rods to the plurality of IGBT elements.

4. The PTC heater of claim 2, wherein the PTC heater parts are composed of a first PTC heater part and a second PTC heater part arranged in parallel at a position spaced apart from each other in the horizontal direction within the air conditioning case.

5. The PTC heater of claim 4, wherein:
one side portion of the heat sink is installed at the upper or the lower portion of the frame to couple with the plurality of IGBT elements to heat-exchange; and
the other side portion of the heat sink is installed at the one side portion of the frame to couple with the control module to heat-exchange.

6. The PTC heater of claim 5, wherein the one side portion of the heat sink is formed in order that an area of a region facing the first PTC heater part is equal to an area of a region facing the second PTC heater part.

7. The PTC heater of claim 4, wherein the control module adjusts the heat generation amount of the heater rods of the first PTC heater part according to a driver's seat target temperature value and adjusts the heat generation amount of the heater rods of the second PTC heater part according to a passenger's seat target temperature value.

8. The PTC heater of claim 4, wherein a horizontal direction cross-sectional area of the first PTC heater part is equal to a horizontal direction cross-sectional area of the second PTC heater part.

9. The PTC heater of claim 4, wherein a separation wall of insulation material is included that fills a space between the first and second PTC heater parts to define the first and second PTC heater parts.

10. The PTC heater of claim 9, wherein the separation wall is integrally formed with the frame.
